(19) United States
(12) Patent Application Publication
(10) Pub. No.: US 2025/0155659 A1
(43) Pub. Date: May 15, 2025

(54) PHOTONIC PACKAGE AND METHOD FOR FORMING THE SAME

(71) Applicant: TAIWAN SEMICONDUCTOR MANUFACTURING COMPANY LTD., HSINCHU (TW)

(72) Inventors: I OUYANG, TAINAN CITY (TW); LI-FENG TENG, HSINCHU CITY (TW); FANG-LAN CHU, TAICHUNG CITY (TW); WEI-CHENG WU, HSINCHU COUNTY (TW); HARRY-HAKLAY CHUANG, HSINCHU COUNTY (TW)

(21) Appl. No.: 18/506,154

(22) Filed: Nov. 10, 2023

(51) Int. Cl. G02B 6/42

(52) U.S. Cl. CPC G02B 6/4279; G02B 6/4283

(57) ABSTRACT

A method of producing a photonic package is provided. A first wafer comprising a plurality of optical dies is disposed over a carrier, wherein each of the optical dies include a front side and a back side opposite to the front side, and wherein the front side of each of the optical dies face the carrier. The first wafer is bonded to a second wafer including a plurality of electronic dies, wherein each of the electronic dies include a front side and a back side opposite to the front side, and wherein the front side of each of the optical dies face the back side of each of the electronic dies, respectively. The carrier is removed from the first wafer. The bonded first wafer and second wafer is divided into a plurality of photonic package.

### BACKGROUND

Optical signaling and processing have been increasingly used in recent years for signal transmission and processing in optical fiber-related applications.

Optical signaling and processing are often combined with electrical signaling and processing for signal transmission. For example, optical fibers are used for long-range signal transmission, while electrical signals are used for short-range signal transmission as well as processing and controlling. Accordingly, devices that include integrated optical components and electrical components are used for conversion between optical signals and the electrical signals, as well as processing of the optical signals and the electrical signals.

The existing packaging process can only produce photonic packages of integrating optical components and electrical components delivering data rate of 100 Gbs radio-frequencies (RF) signals. In addition, in advanced-technology-node photonic packages, high parasitic of RF caused by microbumps (μbumps) cause the bandwidth between the optical components and electrical components be suppressed and cannot meet the goal of having data rate of 200 Gbs RF signals. Moreover, the existing packaging process includes a step of forming a deep through-silicon-via (TSV) in the electrical components having a depth of around 100 μm, which requires extensive efforts in fine-tuning the process parameters.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart representing a method for forming a photonic package according to aspects of the present disclosure.

FIG. 2 is a flowchart representing a method for forming a photonic package according to aspects of the present disclosure.

FIG. 3 illustrates a schematic cross-sectional view of a photonic package in accordance with some embodiments of the present disclosure.

FIG. 4 illustrates a schematic cross-sectional view of a photonic package in accordance with some embodiments of the present disclosure.

FIGS. 5A to 5J are schematic drawings various stages in a formation of a photonic package according to aspects of the present disclosure in one or more embodiments, wherein FIG. 5A is a perspective view, and FIGS. 5B-5J are partially enlarged views taken from FIG. 5A.

FIGS. 6A to 6G are schematic drawings in various stages in a formation of a photonic package according to aspects of the present disclosure in one or more embodiments, wherein FIG. 6A is a perspective view, and FIGS. 6B-6G are partially enlarged views taken from FIG. 6A.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective test measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially.” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In the present disclosure, various aspects of photonic packages and formation methods thereof are provided. Three-dimensional (3D) packages including both optical devices and electrical devices and methods of forming the same are provided, in accordance with some embodiments. In some embodiments, a face-to-back wafer-on-wafer stacked process for producing a plurality of photonic packages of an electrical component and a photonic component is provided. In some embodiments, a face-to-face wafer-on-wafer stacked process for producing a plurality of photonic packages of an electrical component and a photonic component is provided. Intermediate stages of forming the photonic packages are illustrated, in accordance with some embodiments. Some variations of some embodiments are discussed. Throughout the various descriptions and illustrations, like reference numbers are used to designate like elements.

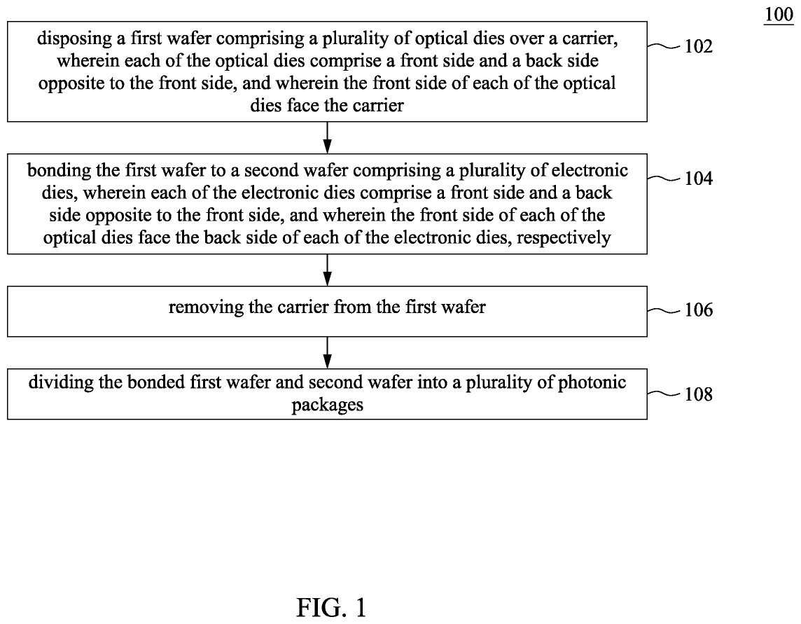

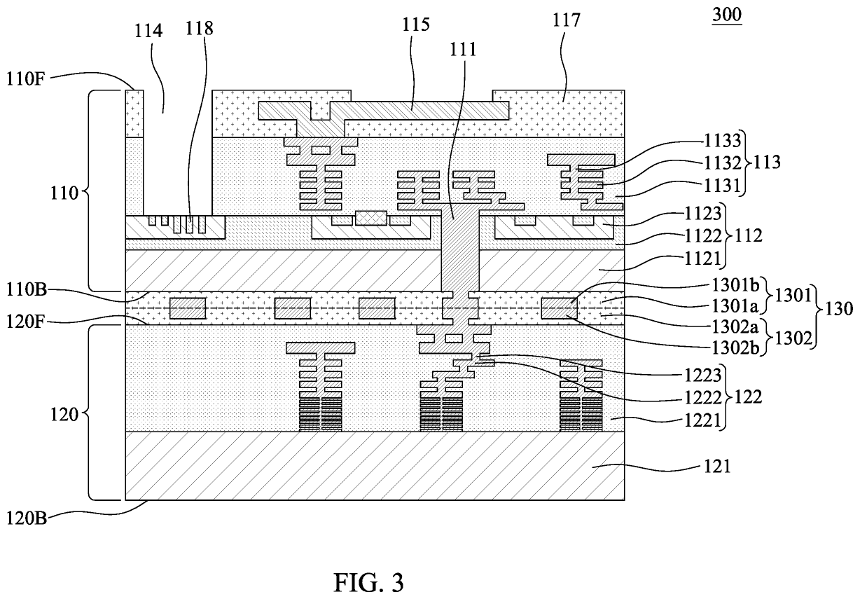

Please refer to FIG. 1. FIG. 1 illustrates a flowchart of a method 100 for forming a photonic package (See FIG. 3 and the accompanying descriptions below for details of the structure of the photonic package 300) according to aspects of the present disclosure. The method 100 includes a number of operations and will be further described according to one or more embodiments. It should be noted that the operations of the method 100 may be rearranged or otherwise modified within the scope of the various aspects. It should be further noted that additional processes may be provided before, during, and after the method 100, and that some other processes may just be briefly described herein. Thus, other implementations are possible within the scope of the various aspects described herein.

The method 100 begins with operation 102 in which a first wafer including a plurality of optical dies is disposed over a carrier. Each of the optical dies include a front side and a back side opposite to the front side. The front side of each of the optical dies face the carrier. The method 100 proceeds with operation 104 in which the first wafer is bonded to a second wafer including a plurality of electronic dies. Each of the electronic dies include a front side and a back side opposite to the front side. The front side of each of the optical dies face the back side of the each of the electronic dies, respectively. The method 100 proceeds with operation 106 in which the carrier is removed from the first wafer. The method 100 proceeds with operation 108 in which the bonded first wafer and second wafer is divided into a plurality of photonic packages.

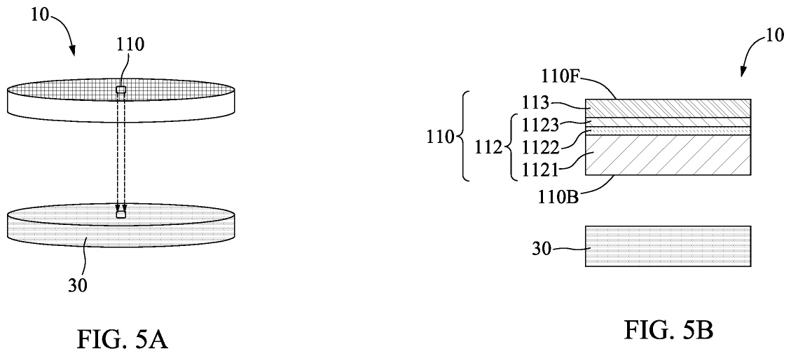

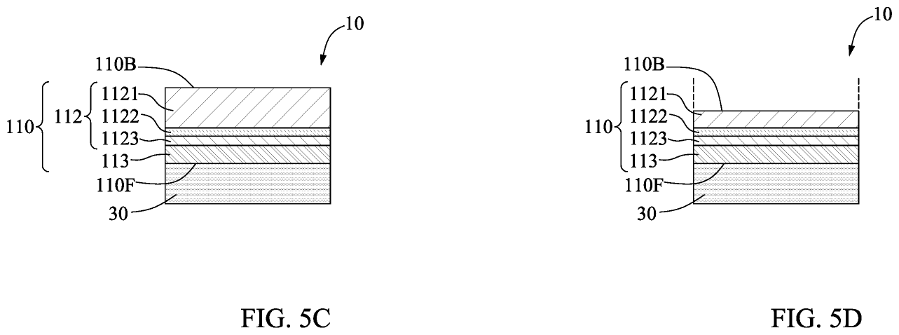

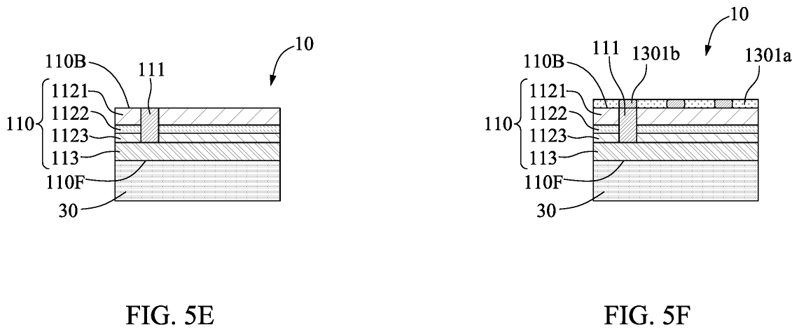

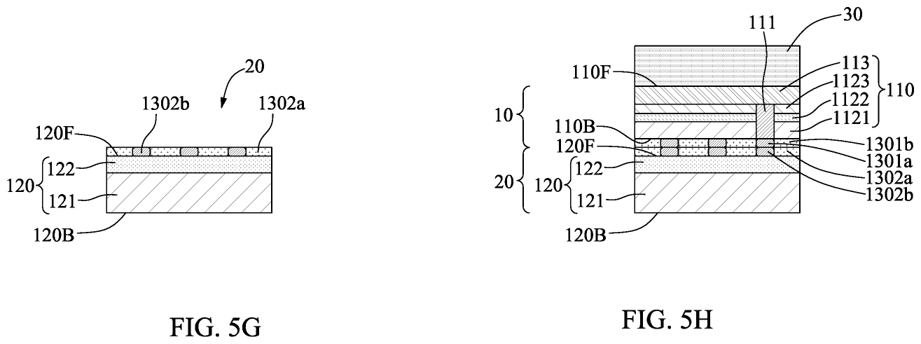

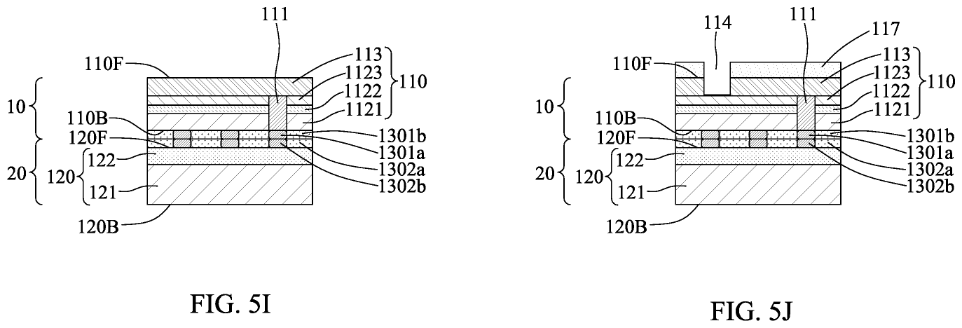

Details for carrying out the operations 102, 104, 106 and 108 of the method 100 are explained below with reference to FIGS. 5A to 5I.

Please refer to FIG. 5A. FIG. 5A illustrates a perspective view of some embodiments of the method 100. As illustrated by FIG. 5A, a first wafer 10 including a plurality of optical dies 110 is provided. In some embodiments, a carrier 30 of a size corresponding to the first wafer 10 is provided. FIG. 5B illustrates a partially enlarged view of the optical die 110 and the carrier 30 of FIG. 5A. In some embodiments, the first wafer 10 has a front side 110F and a back side 110B opposite to the front side 110F. FIG. 5C illustrates a partially enlarged view of the optical die 110 and the carrier 30 of some embodiments corresponding to operation 102. As illustrated by FIG. 5C, the first wafer 10 is disposed over the carrier 30. In some embodiments, the first wafer 10 is flipped before being disposed over the carrier 30 so that the front side 110F of each of the optical dies 110 faces the carrier 30. In some embodiments, an adhesive (not shown) may be used to attach the first wafer 10 to the carrier 30.

FIG. 5D illustrates a partially enlarged view of the optical die 110 and the carrier 30 of some embodiments of the method 100. As illustrated by FIG. 5D, in some embodiments, the first wafer 10 is thinned down before the following operations. In some embodiments, the back side 110B of the optical die 110 is subjected to a thinning process and an overall thickness of the die substrate 112, which includes a bulk substrate 1121, the insulating layer 1122 and the semiconductor layer 1123, is reduced (i.e., a thickness of the bulk substrate 1121 is reduced).

FIG. 5E illustrates a partially enlarged view of some embodiments of the method 100. After the thickness of the bulk substrate 1121 of the first wafer 10 is reduced, a through-via 111 may be formed by forming a through-via opening penetrating the bulk substrate 1121, the insulating layer 1122 and the semiconductor layer 1123 from the back side 110B to the front side 110F, and filling the opening with a conductive material to form the through-via 111.

FIGS. 5F to 5H illustrate partially enlarged views of some embodiments corresponding to operation 104. Referring to FIG. 5F, in some embodiments, a first bonding structure 1301 is formed over the back side 110B of the optical die 110. In some embodiments, the first bonding structure 1301 include a plurality of first conductive pads 1301b embedded in a first dielectric layer 1301a, and the second bonding structure 1302 include a plurality of second conductive pads 1302b embedded in a second dielectric layer 1302a. Referring to FIG. 5G, a second wafer 20 including a plurality electronic dies 120 is provided. In some embodiments, and a second bonding structure 1302 is formed over the front side 120F of the electronic die 120. Referring to FIG. 5G, the first wafer 10 and the carrier 30 are flipped so that the front side 110F of the first wafer 10 is facing upward again. Sequentially, the first wafer 10 is bonded to the second wafer 20 with the back side 110B by bonding the first bonding structure 1301 to the second bonding structure 1302. In other words, the optical die 110 and the electronic die 120 are bonded. As mentioned above, the back side 110B of the optical die 110 is bonded to the front side 120F of the electronic die 120.

In some embodiments, the first conductive pads 1301b and the second conductive pads 1302b are arrayed in a manner so that when the first wafer 10 and the second wafer 20 are bonded, the first conductive pads 1301b on each of the optical dies 110 of the first wafer 10 are physically and electrically connected to the corresponding second conductive pads 1302b on the electronic dies 120 of the second wafer 20, and the first dielectric layer 1301a is physically connected to the second dielectric layer 1302a. In some embodiments, at least one of the first conductive pads 1301b on each of the optical dies 110 of the first wafer 10 is physically connected to the through-via 111 of each of the optical dies 110 of the first wafer 10.

FIG. 51 illustrates a partially enlarged view of some embodiments corresponding to operation 106. As illustrated by FIG. 51, the carrier 30 is removed from the back side of the first wafer 10. In some embodiments, after the carrier 30 is removed, the front side 110F of the first wafer 10 is exposed.

FIG. 5J illustrates a partially enlarged view of some embodiments of the method 100. As illustrated by FIG. 5J, a passivation layer 117 may be formed on the front side 110F of each of the optical dies 110 of the first wafer 10. In some embodiments, at least one opening 114 may be formed by photolithography patterning, followed by etching the passivation layer 117 and the interconnect structure 113 of each of the optical dies 110 of the first wafer to form the openings 114. In some embodiments, after the opening(s) 114 is formed, the bonded first wafer 10 and second wafer 20 are divided into a plurality of photonic packages.

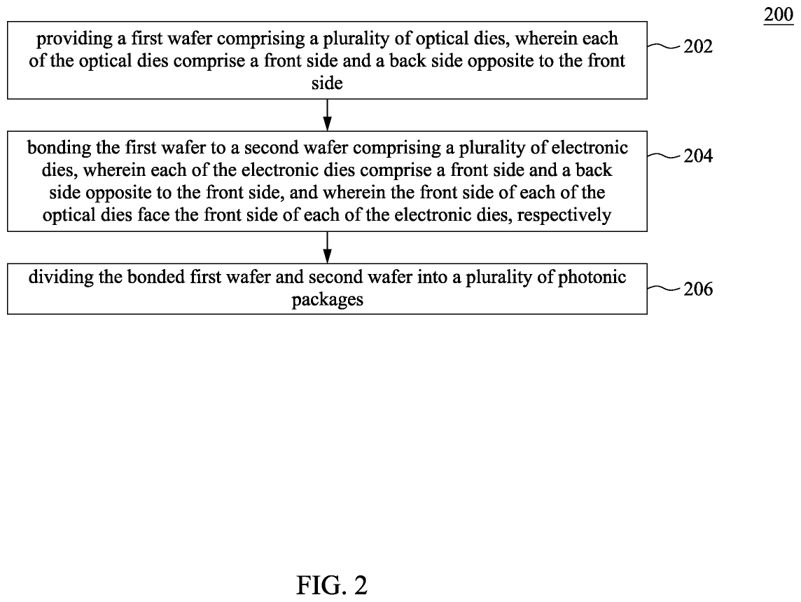

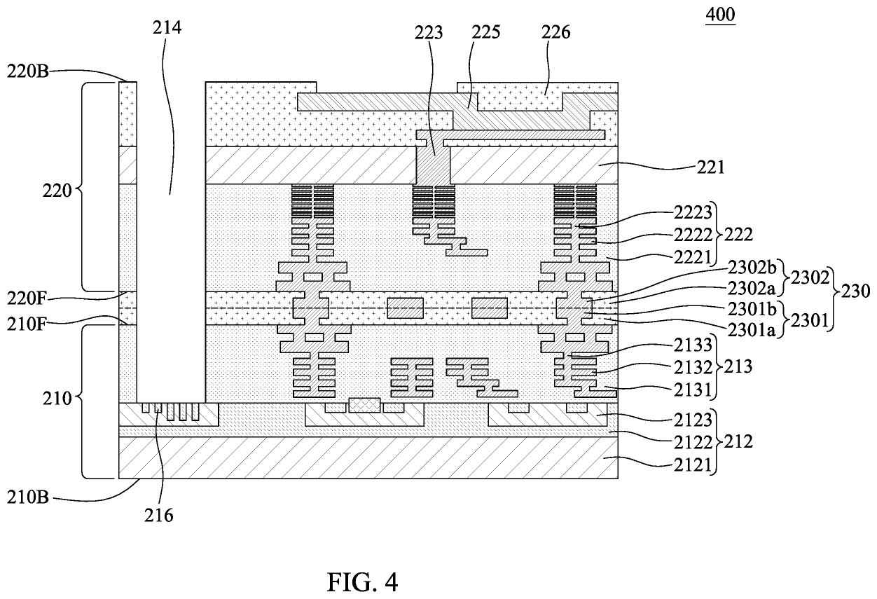

Please refer to FIG. 2. FIG. 2 illustrates a flowchart of a method 200 for forming a photonic package (See FIG. 4 and the accompanying descriptions below for details of the structure of the photonic package 400) according to aspects of the present disclosure. The method 200 includes a number of operations and will be further described according to one or more embodiments. It should be noted that the operations of the method 200 may be rearranged or otherwise modified within the scope of the various aspects. It should be further noted that additional processes may be provided before, during, and after the method 200, and that some other processes may just be briefly described herein. Thus, other implementations are possible within the scope of the various aspects described herein.

The method 200 begins with operation 202 in which a first wafer including a plurality of optical dies is provided. Each of the optical dies include a front side and a back side opposite to the front side. The method 200 proceeds with operation 204 in which the first wafer is bonded to a second wafer including a plurality of electronic dies. Each of the electronic dies include a front side and a back side opposite to the front side. The front side of each of the optical dies face the front side of the each of the electronic dies, respectively. The method 200 proceeds with operation 206 in which the bonded first wafer and second wafer is divided into a plurality of photonic packages.

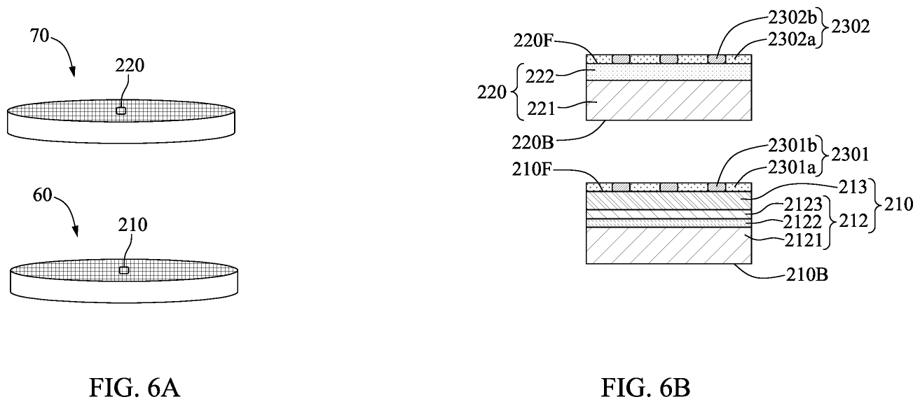

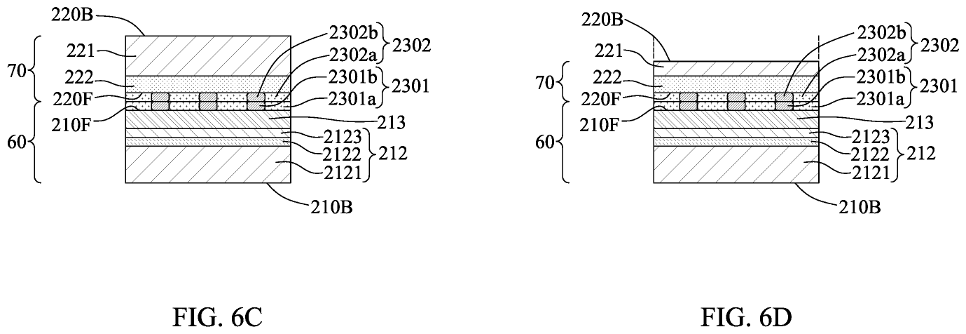

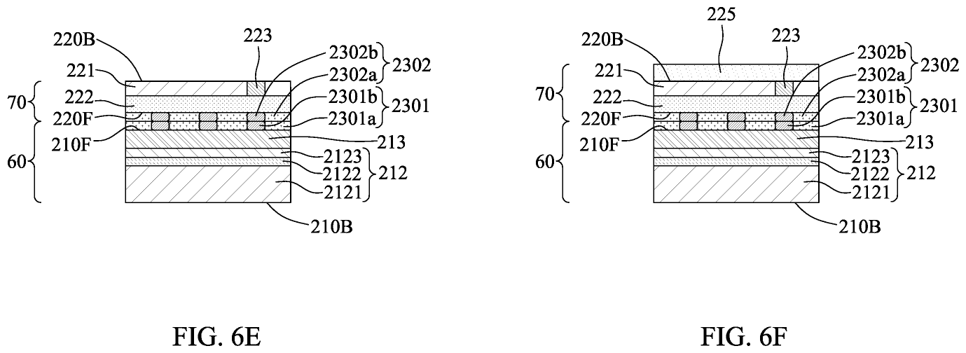

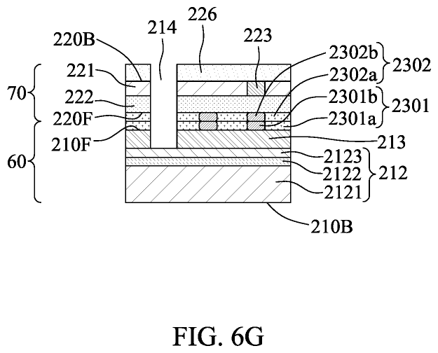

Details for carrying out the operations 202, 204, and 206 of the method 200 are explained below with reference to FIGS. 6A to 6G.

Please refer to FIG. 6A. FIG. 6A illustrates a perspective view of some embodiments of the method 200. As illustrated by FIG. 6A, a first wafer 60 including a plurality of optical dies 210 and a second wafer 70 including a plurality of electronic dies 220 are provided. FIG. 6B illustrates a partially enlarged view of the optical die 210 of the first wafer 60 and the electronic die 220 of the second wafer 70 of some embodiments corresponding to operation 202. The first wafer 60 has a front side 210F and an opposite back side 210B, and the second wafer 70 has a front side 220F and a back side 220B opposite to the front side 220F. In FIG. 6B, the front side 210F of the optical die 210 and the front side 220F of the electronic die 220 both face upward. In some embodiments, a first bonding structure 2301 is formed over the front side 210F of the optical die 210, and a second bonding structure 2302 is formed over the front side 220F of the electronic die 220. In some embodiments, the first bonding structure 2301 include a plurality of first conductive pads 2301b embedded in a first dielectric layer 2301a, and the second bonding structure 2302 include a plurality of second conductive pads 2302b embedded in a second dielectric layer 2302a.

FIG. 6C illustrates a partially enlarged view of the optical die 210 of the first wafer 60 and the electronic die 220 of the second wafer 70 of some embodiments corresponding to operation 204. As illustrated by FIG. 6C, the second wafer 70 is flipped so that the front side 220F is facing downward, and then is bonded to the first wafer 60 by bonding the first bonding structure 2301 to the second bonding structure 2302 so that the front side 210F of the first wafer 60 faces the front side 220F of the second wafer 70. In some embodiments, the first conductive pads 2301b and the second conductive pads 2302b are arrayed in a manner so that when the first wafer 60 and the second wafer 70 are bonded, the first conductive pads 2301b on each of the optical dies 210 of the first wafer 60 are physically connected to the corresponding second conductive pads 2302b on each of the electronic dies 220 of the second wafer 70, and the first dielectric layer 2301a and the second dielectric layer 2302a are physically bonded. In some embodiments, at least one of the bonded first conductive pads 2301b of each of the optical dies 210 of the first wafer 60 and the corresponding second conductive pad 2302b of each of the electronic dies 220 of the second wafer 70 is physically connected to an interconnect structure 213 of the optical die 210 of the first wafer 60 and an interconnect structure 222 of the electronic die 220 of the second wafer 70. In some embodiments, two or more of the bonded first conductive pads 2301b of each of the optical dies 210 of the first wafer 60 and corresponding second conductive pads 2302b of each of the electronic dies 220 of the second wafer 70 are physically connected to the interconnect structure 213 of the optical die 210 the first wafer 60 and the interconnect structure 222 of the electronic die 220 of the second wafer 70.

FIG. 6D illustrates a partially enlarged view of the optical die 210 of the first wafer 60 and the electronic die 220 of the second wafer 70 of some embodiments of the method 200. As illustrated by FIG. 6D, the back side of the second wafer 70 undergoes a polishing process, such as a chemical-mechanical polishing, to reduce an overall thickness of a die substrate 221 of each of the electronic dies 220 of the second wafer 70. FIG. 6E illustrates a partially enlarged view of the optical die 210 of the first wafer 60 and the electronic die 220 of the second wafer 70 of some embodiments of the method 200. As illustrated by FIG. 6E, after the overall thickness of the die substrate 221 of each of the electronic dies 220 of the second wafer 70 is reduced, at least one through-via 223 penetrating the die substrate 221 of the second wafer 70 from the back side 220B to the front side 220F of each of the electronic dies 220 of the second wafer 70 is formed. In some embodiments, after the overall thickness of the die substrate 221 of the second wafer 70 is reduced, at least one through-via 223 may be formed by photolithography patterning, followed by etching the die substrate 221 to form through-via openings, and filling the openings to form the through-via 223. In some embodiments, the at least one through-via 223 of each of the electronic dies 220 of the second wafer 70 is electrically connected to the interconnect structure 222 of the second wafer 70.

FIG. 6F illustrates a partially enlarged view of the optical die 210 of the first wafer 60 and the electronic die 220 of the second wafer 70 of some embodiments of the method 200. As illustrated by FIG. 6F, a passivation layer 226 may be formed on the back side 220B of each of the electronic dies 220 of the second wafer 70. Further, a top metal bond pad layer 225 (please refer to FIG. 4) may be disposed in the passivation layer 226. In some embodiments, the top metal bond pad layer 225 is physically and electrically connected to the through-via 223 of each of the electronic dies 220 of the second wafer 70. Further, the though-via 223 may electrically connect the top metal bond pad layer 225 to the interconnect structure 222.

FIG. 6G illustrates a partially enlarged view of the optical die 210 of the first wafer 60 and the electronic die 220 of the second wafer 70 of some embodiments of the method 200. As illustrated by FIG. 6G, in some embodiments, a grating coupler opening 214 may be formed by photolithography patterning, followed by etching the passivation layer 226 and the die substrate 221 of each electronic dies 220 of the second wafer 70, the second bonding structure 2302, the first bonding structure 2301, the dielectric layer 2131 (shown in FIG. 4) of the interconnect structure 213 of each of the optical dies 210 of the first wafer 60 to form the grating coupler opening(s) 214. In some embodiments, after the at least one grating coupler opening(s) 214 are formed, the bonded first wafer 60 and second wafer 70 are divided into a plurality of photonic packages 400.

In some embodiments, a semiconductor package structure is provided. The semiconductor package structure includes a first die and a second die. The first die includes a first die substrate, a first interconnect structure over the first die substrate, a first dielectric layer over the first die substrate, and first conductive pads embedded in the first dielectric layer. The second die includes a second die substrate, a second interconnect structure over the second die substrate, a second dielectric layer over the second die substrate, and second conductive pads embedded in the second dielectric layer. The first dielectric layer and the second dielectric layer, and the first conductive pads and the second conductive pads are connected to each other respectively to form a bonding structure. One of the first die and the second die is an optical die and the other one of the first die and the second die is an electronic die.

In some embodiments, the semiconductor package structure further includes a through-via penetrating the first die substrate. In some embodiments, the through-via physically connects the first interconnect structure and the bonding structure. In some embodiments, the semiconductor package structure further includes a through-via penetrating the second die structure and physically connecting the second interconnect structure. In some embodiments, the semiconductor package structure further includes a grating coupler opening on the first die substrate. In some embodiments, the semiconductor package structure may be a photonic package. Some embodiments of the variations of the semiconductor package structure of the present disclosure are discussed below.

In some embodiments, the first die of the semiconductor package structure may be an optical die and the second die of the semiconductor package structure may be an electrical die. Please refer to FIG. 3. FIG. 3 illustrates a schematic cross-sectional view of a photonic package 300. The photonic package 300 includes an optical die 110 having a front side 110F and a back side 110B opposite to the front side 110F, a through-via 111 penetrating a die substrate 112 of the optical die 110 from the back side 110B to the front side 110F, an electronic die 120 including a front side 120F and an opposite back side 120B, and a bonding structure 130 disposed between the back side 110B of the optical die 110 and the front side 120F of the electronic die 120 in accordance with some embodiments of the present disclosure. In some embodiments, the optical die 110 may include an interconnect structure 113 formed on the optical die 110 at its front side 110F. In some embodiments, the die substrate 112 may be a silicon-on-insulator (SOI) substrate. The SOI substrate may include an insulating layer 1122 over a bulk substrate 1121, and a semiconductor layer 1123 over the insulating layer 1122. The bulk substrate 1121 may include, for example, a material such as glass, ceramic, dielectric, a semiconductor, the like, or a combination thereof. In some embodiments, the bulk substrate 1121 is a semiconductor substrate, which may be doped or undoped. In some embodiments, the semiconductor substrate may include silicon, germanium, a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GalnP, and/or GaInAsP; or combinations thereof. The insulating layer 1122 may include, for example, a silicon oxide or the like. The semiconductor layer 1123 may be a silicon layer, and the silicon layer may be an epitaxial silicon layer, but the disclosure is not limited thereto.

In some embodiments, the through-via 111 may include a conductive material. In some embodiments, the conductive material may include copper, copper alloys, aluminum, silver, gold, and combinations thereof. The through-via 111 may penetrate the semiconductor layer 1123, the insulating layer 1122 and the bulk substrate 1121. In some embodiments, the interconnect structure 113 includes a dielectric structure 1131, a plurality of metallization layers 1132 disposed in the dielectric structure 1131, and a plurality of vias 1133 electrically connecting the metallization layers 1132. The interconnect structure 113 may be referred to as a back-end-of-line (BEOL) interconnect structure. In some embodiments, the dielectric structure 1131 may include one or more dielectric layers. In some embodiments, the through-via 111 penetrates through the die substrate 112 of the optical die. In some embodiments, the interconnect structure 113 of the optical die 110 is physically connected to the through-via 111. In some embodiments, the through-via 111 has a depth less than approximately 10 μm.

In some embodiments, the optical die 110 further includes a passivation layer 117 and a top metal bond pad layer 115 disposed in the passivation layer 117. Further, the top metal bond pad layer 115 is physically and electrically connected to the interconnect structure 113 of the optical die 110. In some embodiments, the photonic package 100 may comprise an opening 114, such as a grating coupler opening, formed at the front side 110F of the optical die 110. In some embodiments, the opening 114 penetrates the passivation layer 117 and the dielectric structure 1131 of the interconnect structure 113. In some embodiments, the opening 114 has a bottom over the insulating layer 1122. A grating coupler 118 is exposed through the bottom of the opening 114.

In some embodiments, the electronic die 120 may include, for example, semiconductor devices, dies, or chips that communicate with the photonic components using electrical signals. It should be noted that one electronic die 120 is shown in FIG. 3, but a photonic package may include two or more electronic dies 120 in other embodiments.

In some embodiments, the electronic die 120 may include a die substrate 121 and an interconnect structure 122 formed at the front side 120F of the electronic die 120. The die substrate 121 of the electronic die 120 may include integrated circuits for interfacing with the photonic components, such as circuits for controlling operation of the photonic components. For example, the die substrate 121 of the electronic die 120 may include controllers, drivers, transimpedance amplifiers, the like, or combinations thereof. In some embodiments, the electronic die 120 may also include a CPU. In some embodiments, the die substrate 121 of the electronic die 120 includes circuits for processing electrical signals received from photonic components, such as for processing electrical signals received from a photonic component comprising a photodetector. In some embodiments, the die substrate 121 of the electronic die 120 may control high-frequency signaling of the photonic components according to electrical signals (digital or analog) received from another device or die. In some embodiments, the electronic die 120 may be an electronic integrated circuit (EIC) or the like that provides serializer/deserializer (SerDes) functionality. In such manner, the electronic die 120 may act as part of an I/O interface between optical signals and electrical signals within a photonic package. In some embodiments, the photonic package described herein could be considered system-on-chip (SoC) or system-on-integrated-circuit (SoIC) devices. In some embodiments, the interconnect structure 122 includes a dielectric structure 1221, a plurality of metallization layers 1222 disposed in the dielectric structure 1221, and a plurality of vias 1223 electrically connecting the metallization layers 1222. In some embodiments, the dielectric structure 1221 may include one or more dielectric layers. The interconnect structure 122 may be referred to as a back-end-of-line (BEOL) interconnect structure.

In some embodiments, the bonding structure 130 may be a hybrid-bonding structure. In some embodiments, the bonding structure 130 may include a first bonding structure 1301 bonded to a second bonding structure 1302. The first bonding structure 1301 is formed on the back side 110B of the optical die 110 and the second bonding structure 1302 is formed on the front side 120F of the electronic die 120. In some embodiments, the first bonding structure 1301 may include a first dielectric layer 1301a and a plurality of first conductive pads 1301b embedded in the first dielectric layer 1301a and the second bonding structure 1302 may include a second dielectric layer 1302a and a plurality of second conductive pads 1302b embedded in the second dielectric layer 1302a. In some embodiments, each of the first conductive pads 1301b are bonded to and aligned with the second conductive pads 1302b, and the first dielectric layer 1301a is bonded to the second dielectric layer 1302a, to form the bond structure 130. In some embodiments, the first conductive pads 1301b and the second conductive pads 1302b may include metal or metal alloys, such as copper, tungsten, gold, platinum, palladium, nickel, tin, or the like, or alloys and combinations thereof. In some embodiments, the bonding structure 130 is disposed between the interconnect structure 122 of the electronic die 120 and the back side 110B of the optical die 110. In some embodiments, at least one of the bonded first conductive pad 1301b and second conductive pad 1302b is physically connected to the interconnect structure 122 of the electronic die 120 and is physically connected to the through-via 111 of the optical die 110. In some embodiments, the optical die 110 is electrically connected to the electronic die 120 through the at least one bonded first conductive pad 1301b and the second conductive pad 1302b of the bonding structure 130. In some embodiments, the photonic package 300 may include a switch formed on the front side 120F of the electronic die 120.

In some embodiments, the bonding structure 130 helps to bond the optical die 110 and the electronic die 120. Further, the bonding structure 130 helps to build an electrical connection between the optical die 110 and the electronic die 120. As shown in FIG. 3, the through-via 111 is coupled to at least one of the bonded first conductive pad 1301b and the second conductive pad 1302b of the bonding structure 130, while the one of the bonded first conductive pad 1301b and the second conductive pads 1302b may be coupled to the interconnect structure 122 of the electronic die 120. Accordingly, the interconnect structure 113 of the optical die 110 and interconnect structure 122 of the electronic die 120 are electrically connected by the through-via 111 and the bonding structure 130. In other words, electrical connection between the optical die 110 and the electronic die 120 is built. Further, the photonic package 300 has the electronic die 120 and the optical die 110 face-to-back bonded.

In some embodiments, optical signals received by the optical die 110 are transmitted to the electronic die 120 by a light source, such as laser, and received by the grating coupler 118 located beneath the opening 114. The optical signals received by the optical die 110 are then transferred to electrical signals and transmitted through the through-via 111, the bonding layer 130, to the interconnect structure 122 of the electronic die 120.

In some embodiments, electrical signals received by the top metal bond pad layer 115 of the optical die 110 are transmitted to the electronic die 120 through its electrically connection with the interconnect structure 113 and the through-via 111 of the optical die 110, the bonding structure 130 between the optical die 110 and the electronic die 120, and the interconnect structure 122 of the electronic die 120.

Please refer to FIG. 4. FIG. 4 illustrates a schematic cross-sectional view of a photonic package 400 according to some embodiments of the present disclosure. The photonic package 400 includes an electronic die 220 having a front side 220F and a back side 220B opposite to the front side 220F, a through-via 223 penetrating a die substrate 221 of the electronic die 220 from the back side 220B to the front side 220F, an optical die 210 including a front side 210F and a back side 210B opposite to the front side 210F, and a bonding structure 230 disposed between the front side 210F of the optical die 210 and the front side 220F of the electronic die 220 in accordance with some embodiments of the present disclosure. In some embodiments, the optical die 210 may include a die substrate 212 and an interconnect structure 213 formed on the front side 210F of the optical die 210. In some embodiments, the die substrate 212 may be a silicon-on-insulator (SOI) substrate. The SOI substrate may include an insulating layer 2122 over a bulk substrate 2121, and a semiconductor layer 2123 over the insulating layer 2122. Materials used to form the bulk substrate 2121, the insulating layer 2212 and the semiconductor layer 2123 may be similar to those described above; therefore, details of the materials are omitted for brevity.

In some embodiments, the through-via 223 may include a conductive material. In some embodiments, the conductive material may include copper, copper alloys, aluminum, silver, gold, and combinations thereof.

In some embodiments, the electronic die 220 may include, for example, semiconductor devices, dies, or chips that communicate with the photonic components using electrical signals. It should be noted that one electronic die 220 is shown in FIG. 2, but a photonic package may include two or more electronic dies 220 in other embodiments.

In some embodiments, the electronic die 220 may include a die substrate 221 and an interconnect structure 222 formed at the front side 220F of the electronic die 220. The die substrate 221 of the electronic die 220 may include integrated circuits for interfacing with the photonic components, such as circuits for controlling operation of the photonic components. For example, the die substrate 221 of the electronic die 220 may include controllers, drivers, transimpedance amplifiers, the like, or combinations thereof. In some embodiments, the electronic die 220 may also include a CPU. In some embodiments, the die substrate 221 of the electronic die 220 includes circuits for processing electrical signals received from photonic components, such as for processing electrical signals received from a photonic component comprising a photodetector. In some embodiments, the die substrate 221 of the electronic die 220 may control high-frequency signaling of the photonic components according to electrical signals (digital or analog) received from another device or die. In some embodiments, the electronic die 220 may be an electronic integrated circuit (EIC) or the like that provides serializer/deserializer (SerDes) functionality. In such manner, the electronic die 220 may act as part of an I/O interface between optical signals and electrical signals within a photonic package. In some embodiments, the photonic package described herein could be considered system-on-chip (SoC) or system-on-integrated-circuit (SoIC) devices. In some embodiments, the interconnect structure 222 includes a dielectric structure 2221, a plurality of metallization layers 2222 disposed in the dielectric structure 2221, and a plurality of vias 2223 electrically connecting the metallization layers 2222. In some embodiments, the dielectric structure 2221 includes one or more dielectric layers.

In some embodiments, the photonic package 200 may include passivation layer 226 disposed over the back side 220B of the electronic die 220. Further, the photonic package 200 includes a top metal bond pad layer 225 disposed in the passivation layer 226 at the back side 220B of the electronic die 220. In some embodiments, the top metal bond pad layer 225 is physically and electrically connected to the through-via 223 of the electronic die 220. In some embodiments, the through-via 223 has a depth less than 10 μm. In other words, the die substrate 221 may have a thickness of less than 10 μm. Further, the though-via 223 may electrically connect the top metal bond pad layer 225 to the interconnect structure 222, as shown in FIG. 2.

In some embodiments, the bonding structure 230 may be a hybrid-bonding structure. In some embodiments, the bonding structure 230 may include a first bonding structure 2301 bonded to a second bonding structure 1302. The first bonding structure 2301 is formed on the front side 210F of the optical die 210 and the second bonding structure 2302 is formed on the front side 220F of the electronic die 220. In some embodiments, the bonding structure 230 may include a first dielectric layer 2301a and a plurality of first conductive pads 2301b embedded in the first dielectric layer 2301a, and the second bonding structure 2302 may include a second dielectric layer 2302a and a plurality of second conductive pads 2302b embedded in the second dielectric layer 2302a. In some embodiments, each of the first conductive pads 2301b are bonded to and aligned with the second conductive pads 2302b, and the first dielectric layer 2301a is bonded to the second dielectric layer 2302a, to form the bonding structure 230. In some embodiments, the first conductive pads 1301b and the second conductive pads 1302b may include metal or metal alloys, such as copper, tungsten, gold, platinum, palladium, nickel, tin, or the like, or alloys and combinations thereof. In some embodiments, the bonding structure 230 is disposed between the interconnect structure 222 formed on the front side 220F of the electronic die 220 and the interconnect structure 213 formed on the front side 210F of the optical die 210. In some embodiments, at least one of the bonded first conductive pad 1301b and second conductive pad 2302b is physically connected to the interconnect structure 222 of the electronic die 220 and is physically connected to the interconnect structure 213 of the optical die 210. In some embodiments, two or more of the plurality of the bonded first conductive pads 2301b and the second conductive pads 2302 are physically connected to the interconnect structure 222 of the electronic die 220 and are physically connected to the interconnect structure 213 of the optical die 210. In some embodiments, the optical die 210 is electrically connected to the electronic die 220 through the at least one bonded first conductive pad 2301b and the second conductive pad 2302b of the bonding structure 230. In some embodiments, the photonic package 400 may include a switch formed on the front side 220F of the electronic die 220.

In some embodiments, the bonding structure 230 helps to bond the optical die 210 and the electronic die 220. Further, the bonding structure 230 helps to build an electrical connection between the optical die 210 and the electronic die 220. As shown in FIG. 4, the interconnect structure 213 of the optical die 210 and interconnect structure 222 of the electronic die 220 are electrically connected by the bonding structure 230. In other words, electrical connection between the optical die 210 and the electronic die 220 is built. Further, the photonic package 200 has the electronic die 220 and the optical die 210 face-to-face bonded.

In some embodiments, the photonic package 400 comprises an opening 214 penetrating through the electronic die 220, the bonding structure 230 and the interconnect structure 213 of the optical die 210. In some embodiments, the opening 214 has a bottom formed on the front side 210F of the optical die 210. In some embodiments, the opening 214 has a bottom over the insulating layer 2122. A grating coupler 216 may be exposed through the bottom of the opening 214.

In some embodiments, optical signals received by the optical die 210 are transmitted to the electronic die 220 by a light source, such as laser, and received by the grating coupler 216 located beneath the opening 214. The optical signals received by the optical die 210 are then transferred to electrical signals and transmitted from the interconnect structure 213 of the optical die 210 to the electronic die 120 through the bonding structure 230 physically and electrically connected to the interconnect structure 213, to the interconnect structure 222 of the electronic die 220. The electrical signals are then transmitted from the interconnect structure 222 of the electronic die 220 to the top metal bond pad layer 225.

In some embodiments, electrical signals received by the top metal bond pad layer 225 of the electronic die 220 are transmitted to the optical die 210 through its electrically connection with the through-via 223 and the interconnect structure 222 of the electronic die 220, the bonding structure 230 between the optical die 210 and the electronic die 220, and the interconnect structure 213 of the optical die 220.

The present disclosure provides photonic packages and methods of forming the photonic packages. By preparing the photonic packages through the aforementioned face-to-back wafer stacked method 100 or the face-to-face wafer stacked method 200, the photonic packages may have a better data rate of 200 Gbs RF signal and much less processing tuning efforts for the 10 times shorter through-via depth, which is less than 10 μm. In addition, the aforementioned face-to-back wafer stacked method 100 and the face-to-face wafer stacked method 200 allow more design flexibility on electric interconnection and chiplet integration between the electronic die and the optical die. Moreover, such face-to-back wafer stacked method 100 and or the face-to-face wafer stacked method 200 produce less interconnect parasitic resistance, and allows the open area of the grating coupler to have a diameter up to 30 μm, which increases I/O bandwidth. To sum up, the face-to-back wafer stacked method 100 and the face-to-face wafer stacked method 500 integrate electronic dies and optical dies without affecting signal integrity and power consumption. In addition, the face-to-back wafer stacked method 100 and the face-to-face wafer stacked method 500 sustain power budget through simple hybrid bonding process without a complicated metal routing. The simple hybrid bonding process dramatically decreases the overall package size and the cost for photonic package production.

In some embodiments, a method of producing a photonic package is provided. A first wafer including a plurality of photonic dies is disposed over a carrier, wherein each of the optical dies include a front side and a back side opposite to the front side, and wherein the front side of each of the optical dies face the carrier. The first wafer is bonded to a second wafer including a plurality of electronic dies, wherein each of the electronic dies include a front side and a back side opposite to the front side, and wherein the front side of each of the optical dies face the back side of each of the electronic dies, respectively. The carrier is removed from the first wafer. The bonded first wafer and second wafer is divided into a plurality of photonic package.

In some embodiments, a method of producing a photonic package is provided. A first wafer including a plurality of optical dies is provided, wherein each of the optical dies include a front side and a back side opposite to the front side. The first wafer is bonded to a second wafer including a plurality of electronic dies, wherein each of the electronic dies include a front side and a back side opposite to the front side, and wherein the front side of each of the optical dies face the front side of each of the electronic dies, respectively. The bonded first wafer and second wafer is divided into a plurality of photonic package.

In some embodiments, a semiconductor package structure is provided. The semiconductor package structure includes a first die and a second die. The first die includes a first die substrate, a first interconnect structure over the first die substrate, a first dielectric layer over the first die substrate, and first conductive pads embedded in the first dielectric layer. The second die includes a second die substrate, a second interconnect structure over the second die substrate, a second dielectric layer over the second die substrate, and second conductive pads embedded in the second dielectric layer. The first dielectric layer and the second dielectric layer, and the first conductive pads and the second conductive pads are connected to each other respectively to form a bonding structure. One of the first die and the second die is an optical die and the other one of the first die and the second die is an electronic die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of producing a photonic package, comprising:
disposing a first wafer comprising a plurality of optical dies over a carrier, wherein each of the optical dies comprise a front side and a back side opposite to the front side, and wherein the front side of each of the optical dies face the carrier;
bonding the first wafer to a second wafer comprising a plurality of electronic dies, wherein each of the electronic dies comprise a front side and a back side opposite to the front side, and wherein the front side of each of the optical dies face the back side of each of the electronic dies, respectively;
removing the carrier from the first wafer, and
dividing the bonded first wafer and second wafer into a plurality of photonic packages.

2. The method of claim 1, further comprising forming at least one through-via penetrating each of the optical dies of the first wafer from the back side to the front side.

3. The method of claim 2, further comprising thinning down the first wafer prior to forming the at least one through-via.

4. The method of claim 1, further comprising forming a grating coupler opening on the front side of each of the optical dies of the first wafer.

5. The method of claim 2, wherein the bonding of the first wafer to the second wafer further comprises:
forming a first bonding structure over the back side of each of the optical dies and a second bonding structure over the front side of each of the electronic dies; and
bonding the first bonding structure with the second bonding structure, wherein the first bonding structure comprises a plurality of first conductive pads embedded in a first dielectric layer and the second bonding structure comprises a plurality of second conductive pads embedded in a second dielectric layer.

6. The method of claim 5, wherein bonding the first bonding structure with the second bonding structure comprises bonding the plurality of first conductive pads with the plurality of second conductive pads, respectively.

7. The method of claim 6, wherein the through-via is coupled to at least one of the plurality of the bonded first and second conductive pads.

8. A method of producing a photonic package, comprising:
providing a first wafer comprising a plurality of optical dies, wherein each of the optical dies comprise a front side and a back side opposite to the front side;
bonding the first wafer to a second wafer comprising a plurality of electronic dies, wherein each of the electronic dies comprise a front side and a back side opposite to the front side, and wherein the front side of each of the optical dies face the front side of each of the electronic dies, respectively; and
dividing the bonded first wafer and second wafer into a plurality of photonic packages.

9. The method of claim 8, further comprising forming at least one through-via penetrating each of the electronic dies of the second wafer from the back side to the front side.

10. The method of claim 9, further comprising thinning down the second wafer prior to forming the at least one through-via.

11. The method of claim 8, further comprising forming a grating coupler opening exposing the front side of each of the optical dies of the first wafer.

12. The method of claim 9, wherein the bonding of the first wafer to the second wafer further comprises:
forming a first bonding structure over the front side of each of the optical dies and a second bonding structure over the front side of each of the electronic dies; and
bonding the first bonding structure with the second bonding structure, wherein the first bonding structure comprises a plurality of first conductive pads embedded in a first dielectric layer and the second bonding structure comprises a plurality of second conductive pads embedded in a second dielectric layer.

13. The method of claim 12, wherein bonding the first bonding structure with the second bonding structure comprises bonding the plurality of first conductive pads with the plurality of second conductive pads, respectively.

14. The method of claim 13, wherein the through-via is coupled to at least one of the plurality of the bonded first and second conductive pads.

15. A semiconductor package structure comprising:
a first die, comprising:
a first die substrate;
a first interconnect structure over the first die substrate;
a first dielectric layer over the first die substrate; and
first conductive pads embedded in the first dielectric layer; and
a second die, comprising:
a second die substrate;
a second interconnect structure over the second die substrate;
a second dielectric layer over the second die substrate; and
second conductive pads embedded in the second dielectric layer;
wherein the first dielectric layer and the second dielectric layer, and the first conductive pads and the second conductive pads are connected to each other respectively to form a bonding structure, and
wherein one of the first die and the second die is an optical die and the other one of the first die and the second die is an electronic die.

16. The semiconductor package structure of claim 15, further comprising a through-via penetrating the first die substrate.

17. The semiconductor package structure of claim 16, wherein the through-via physically connects the first interconnect structure and the bonding structure.

18. The semiconductor package structure of claim 17, further comprising a grating coupler on the first die substrate.

19. The semiconductor package structure of claim 15, further comprising a through-via penetrating the second die structure and physically connecting the second interconnect structure.

20. The semiconductor package structure of claim 19, further comprising a grating coupler on the first die substrate.
